(19) United States
(12) Patent Application Publication
(10) Pub. No.: US 2024/0387336 A1
(43) Pub. Date: Nov. 21, 2024

(54) DIGITALIZED INTERCONNECT REDISTRIBUTION ENABLED CHIPLET PACKAGING

(71) Applicant: Applied Materials, Inc., Santa Clara, CA (US)

(72) Inventor: Guan-Shian CHEN, Sunnyvale, CA (US)

(21) Appl. No.: 18/625,490

(22) Filed: Apr. 3, 2024

Related U.S. Application Data
(60) Provisional application No. 63/504,403, filed on May 25, 2023.
(60) Provisional application No. 63/466,691, filed on May 15, 2023.

(51) Int. Cl. H01L 23/498; H01L 21/48; H01L 21/683; H01L 23/00; H01L 23/544; H01L 25/18

(52) U.S. Cl. CPC H01L 23/49822; H01L 21/486; H01L 21/6836; H01L 23/544; H01L 24/08; H01L 24/80; H01L 25/18; H01L 2223/54426; H01L 2224/08225; H01L 2224/80006; H01L 2224/8013; H01L 2924/1815

(57) ABSTRACT

A method of forming a multichip module includes molding a set of chips in a medium to secure each chip relative to each other chip, mapping a position and orientation of the chips within the molded set of chips based on alignment marks disposed on each chip within the molded set of chips, forming an interconnect substrate including forming a first interconnect layer over a base substrate, patterning the first interconnect layer to include a first plurality of patterned vias that are patterned based at least in part on the mapping, and bonding the interconnect substrate the multichip module, wherein bonding comprises positioning and aligning the interconnect substrate to the molded set of chips such that interconnects of each chip within the molded set of chips are aligned with the first plurality of patterned vias formed in the interconnect substrate.

### CROSS-REFERENCE TO RELATED APPLICATIONS

This application claims the benefit of U.S. Provisional Application Ser. No. 63/504,403, filed on May 25, 2023, and the benefit of U.S. Provisional Application Ser. No. 63/466,691, filed on May 15, 2023, which are both herein incorporated by reference.

### BACKGROUND

### Field

Implementations of the present disclosure relate to apparatus, systems, and methods of digitalized interconnect redistribution enabled chiplet packaging, for example to provide a better area and line input/output density than a 2.5D interposer method, 2D fan-out packaging method, and 2.3D silicon bridge method.

### Description of the Related Art

Electronic devices, such as are included in tablets, computers, copiers, digital cameras, smart phones, control systems, and automated teller machines, among others, often include integrated circuit die(s) for some desired functionality. A heterogeneous integration module (HIM) (which may also be referred to or be a type of multi-chip module (MCM)) is a type of microelectronics device that integrates multiple different chips, materials, components, and/or technologies into a single compact package. This approach allows designers to create more complex and powerful systems by integrating different components, without the need for full system-on-chip integration. For example, this type of device aims to provide a high level of functionality and performance while also reducing the overall size, cost, and complexity of the system. HIMs devices are commonly used in a wide range of applications, including smartphones, wearable devices, and internet of things (IoT) devices, as well as in various fields such as telecommunications, computing, and robotics. They are designed to overcome the limitations of traditional microelectronics devices, which often rely on a single technology or material, by bringing together complementary components and technologies in a single, integrated package. Some examples of HIMS devices include multi-layer microelectronics packages, system-in-package (SiP) devices, and 2D and 3D integrated circuits (3D ICs). These devices can offer improved performance, higher functional density, and better thermal management compared to traditional microelectronics devices. However, combining different components into a single component package can lead to alignment and other integration issues, requiring relatively larger interconnect pitch, resulting in higher interconnect resistivity, or both.

### SUMMARY

According to one or more embodiments, a method of forming a multichip module includes molding a set of chips in a medium to secure each chip relative to each other chip, mapping a position and orientation of the chips within the molded set of chips based on alignment marks disposed on each chip within the molded set of chips, forming an interconnect substrate including forming a first interconnect layer over a base substrate, patterning the first interconnect layer to include a first plurality of patterned vias that are patterned based at least in part on the mapping, and bonding the interconnect substrate the multichip module, wherein bonding comprises positioning and aligning the interconnect substrate to the molded set of chips such that interconnects of each chip within the molded set of chips are aligned with the first plurality of patterned vias formed in the interconnect substrate.

According to one or more embodiments, a method of forming a multichip module includes forming a set of alignment marks on a set of dies to be integrated into a multichip module, the set of dies comprising a first die unit comprising first dies and a second die unit comprising second dies, each die having at least one alignment mark, molding the set of dies in a medium to secure each die relative to each other die, mapping each alignment mark of each die in the set of dies that are molded in the medium, forming an interconnect substrate including forming a first interconnect layer over a base substrate, patterning the first interconnect layer to include a first plurality of patterned vias that are patterned based at least in part on the mapping, and dicing the interconnect substrate into individual interconnect substrate units including a first interconnect substrate unit corresponding to the first die unit and a second interconnect substrate unit corresponding to the second die unit, and bonding the first interconnect substrate unit to the first die unit and the second interconnect substrate unit to the second die unit.

According to one or more embodiments, a packaged multichip module includes a set of chips molded in a medium, each chip having at least one alignment mark, and an interconnect substrate bonded to the set of chips, the interconnect substrate comprising a first interconnect layer formed over a base substrate, and a first plurality of patterned vias formed through the base substrate and the first interconnect layer that are patterned based on a position and orientation of the chips determined based at least in part on a mapping of each alignment mark.

### BRIEF DESCRIPTION OF THE DRAWINGS

So that the manner in which the above-recited features of the disclosure can be understood in detail, a more particular description of the disclosure, briefly summarized above, may be had by reference to implementations, some of which are illustrated in the appended drawings. It is to be noted, however, that the appended drawings illustrate only common implementations of this disclosure and are therefore not to be considered limiting of its scope, for the disclosure may admit to other equally effective implementations.

FIG. 1 is a schematic view of a portion of a multichip module comprising an integrated function chip according to one or more embodiments.

FIGS. 2A-2M illustrate cross-sectional and top views following a series of operations to form a multichip module according to one or more embodiments.

FIG. 3 is a flow diagram for forming a packaged multichip module according to one or more embodiments.

To facilitate understanding, identical reference numerals have been used, where possible, to designate identical elements that are common to the figures. It is contemplated that elements disclosed in one or more implementations may be beneficially utilized on other implementations without specific recitation.

### DETAILED DESCRIPTION

A multichip module (MCM) (or heterogeneous integration module (HIM)) may incorporate a number of semiconductor devices formed on or in a substrate (e.g., chips or chiplets). Examples of interconnection types used for HIMs include 2D fan-out type, 2.3D silicon bridge type, and 2.5D performance gap type.

A 2D fan-out packaging is a type of chip packaging technology that allows multiple chips or dies to be integrated onto a single package using a 2D layout. In this approach, the dies are mounted on a substrate, which is then molded with an insulating material to create a flat surface. The substrate is then etched to create a pattern of electrical interconnects, which connect the dies to each other and to the package's external pins. This packaging technique may allow for increased integration density and reduced form factor, as well as improved thermal performance due to the use of a thin and uniform package. Additionally, 2D fan-out packaging can offer better electrical performance compared to traditional packaging methods such as wire bonding, as the shorter interconnects and reduced parasitics can result in faster signal propagation and lower power consumption.

2.3D Si Bridge packaging is a type of semiconductor packaging technology that enables the integration of multiple dies or chips on a single package using a 2.5D or 3D layout. This approach involves using a silicon interposer or “bridge” that provides high-density electrical connections between the dies and other components, such as memory or sensors. In a 2.3D Si Bridge package, the interposer is thinned down to reduce the distance between the dies and minimize electrical parasitics, resulting in improved performance and power efficiency. This approach can also enable the use of heterogeneous integration, where different types of dies or technologies can be integrated on the same package. 2.3D Si Bridge packaging can offer a range of benefits, including increased performance, higher integration density, reduced power consumption, and improved thermal management, making it an attractive solution for high-performance computing, AI, and other advanced applications.

A multichip module that uses a 2.5D interposer is a type of electronic package that combines multiple chips or dies, that each may be fabricated using different processes and technologies, into a single module. In a 2.5D module, the individual dies are mounted on a silicon or organic interposer, which serves as a bridge between the dies and provides electrical and thermal connections.

In some cases, 2D fan out (X-Y) line space limits are at (2/2 um-5/5 um), which is typically not far from the line patterning capability of a system, but may present concerns of long-term reliability (e.g., on an organic dielectric) due to wafer/substrate global coefficient of thermal expansion (CTE) mismatch by and between one or more wafers and the substrate, CTE being the measure of the ability of a material to expand or contract with temperature changes. This problem may be especially acute for cross multi-die space areas.

In some cases, 2.3D (silicon (Si) Bridge) and 2.5D interposer type approaches use solder bumps (e.g., copper pillar (Cu-Pillar) solder bumps). Such solder bumps are typically associated with a higher electrical resistance than a direct Cu junction. The input/output area density is limited by solder bump pitch.

Embodiments of the present disclosure relate to apparatus, systems, and methods of digitalized interconnect redistribution enabled chiplet packaging, for example to provide a better area and line input/output density than a 2.5D interposer method, 2D fan-out packaging method, and 2.3D silicon bridge method. It is also believed that the disclosed packaging structure and methods provided herein will also provide a lower electrical resistance than 2.5D & 2.3D packaging and better packaging process-induced stress management from a localized direct CTE-compatible RDL stack scheme from traditional 2-D packaging.

One or more embodiments disclosed herein include a method of forming a multichip module, including forming a set of alignment marks on a set of chips to be integrated into a multichip module, each chip having at least one alignment mark, molding the set of chips in a medium to secure each chip relative to each other chip, mapping each alignment mark of for a corresponding chip of the set of chips that are molded in the medium, forming an interconnect substrate having a plurality of vias that are based at least in part on the mapping, and bonding the interconnect substrate to the medium having the molded set of chips.

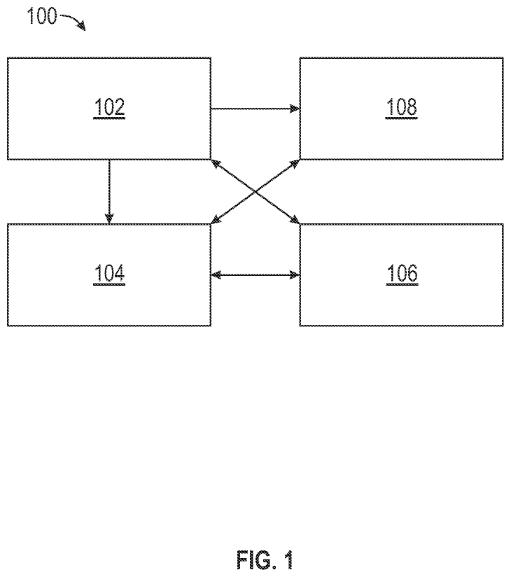

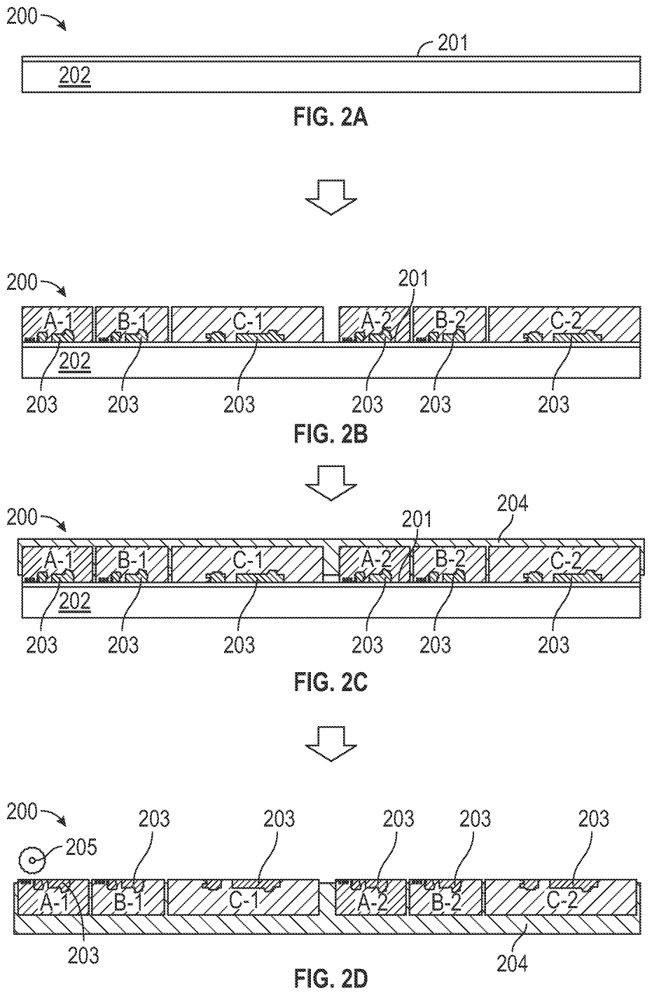

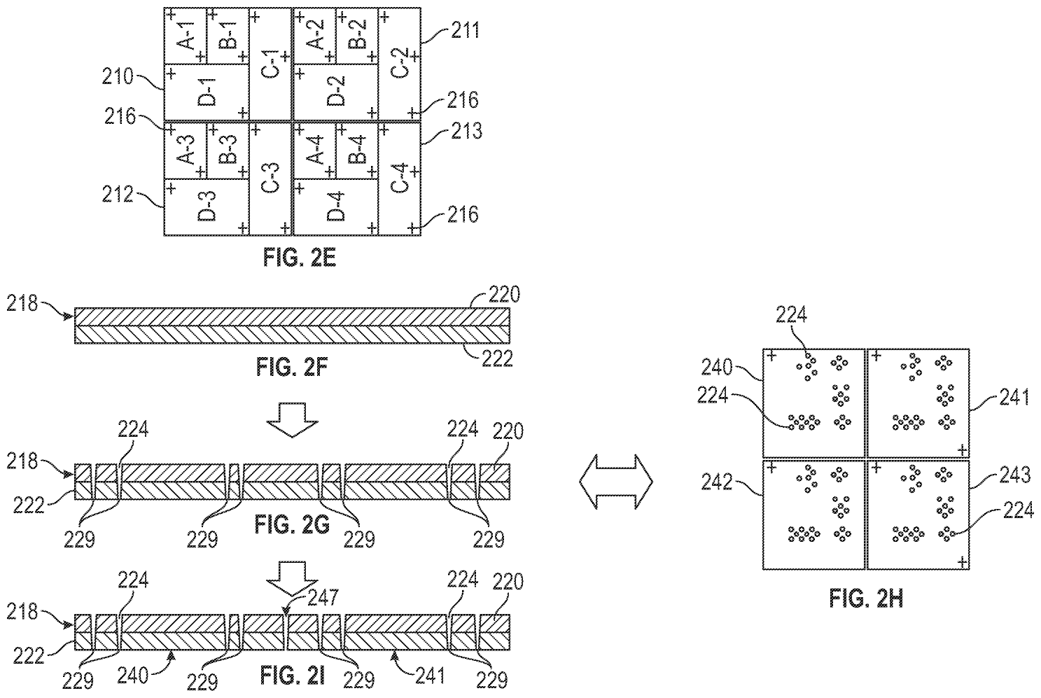

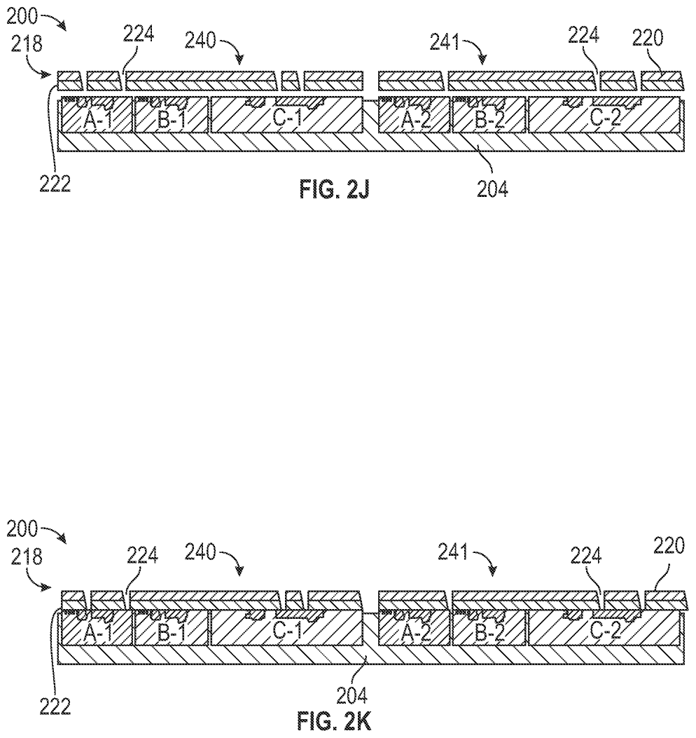

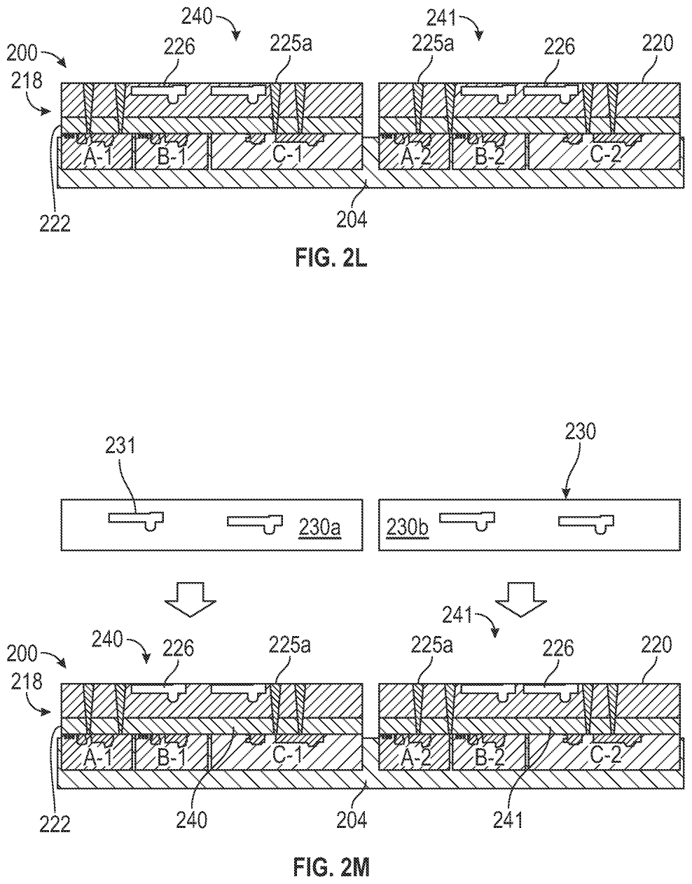

FIG. 1 is a schematic view of a portion of a multichip module 100 comprising an integrated function chip 102 according to embodiments. In one example, the integrated function chip 102 may be connected by a plurality of optical waveguides or electrical trace interconnects to a passive chip (passive) 104, a through-silicon-via (or through-mold-via) chip 106, and a memory chip 108 which all are formed in or disposed on a medium (i.e., a fill material 204 in FIGS. 2C-2D, and 2J-2K). In some embodiments, each of chip of the multchip module 100 are coupled to one another. For example, memory chip 108 is directly coupled to the passive chip 104, the passive chip is directly coupled to the through-silicon-via 106, and so on. In an embodiment, the integrated function chip 102 may include any high-density chip having a high I/O pin count. In one example, the high-density chip has between 100 and 2000 I/O pins or up to and greater than 2000 I/O pin counts. Examples of integrated function chips 102 include but not limited to data center SWITCH chips, artificial intelligence (AI) chips, and the like.

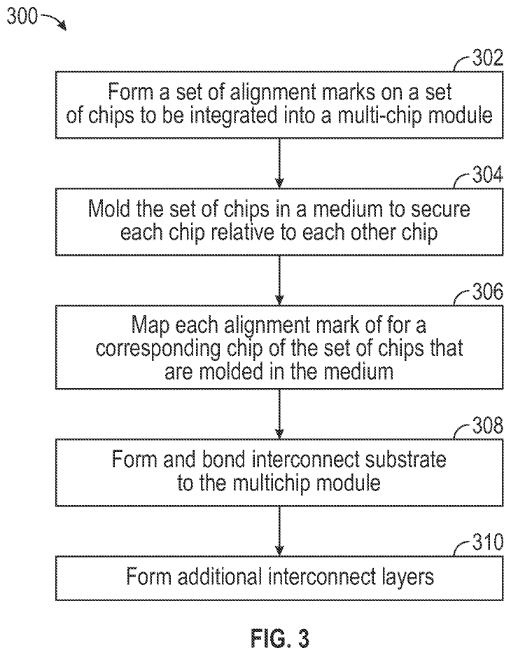

FIGS. 2A through 2M depict cross-sectional and top views following a series of operations used to form a multichip module 200 (which may also be or be referred to as a HIM herein). FIG. 3 is a flow diagram for forming a multichip module.

In some embodiments, the multichip module 200 includes an interconnect structure and associated semiconductor devices (e.g., chiplets, including Active, Passive, or Electrical path chiplets) during formation of the multichip module. In some examples, the formed multichip module 200 may be or be referred to as digitalized interconnect redistribution enabled chiplet packaging.

At operation 302, a set of alignment marks 216 are formed on each chip of a set of chips to be integrated into multichip module 200 (FIG. 2E). In one example, each chip of the set of chips includes at least one alignment mark that is formed by a printing process.

At operation 304 each chip of the set of chips are positioned and then molded into a medium to secure each chip relative to each other chip. In one example, operation 304 includes the operations shown in FIGS. 2A-2E. In some embodiments, as explained above prior to molding the set of chips in the medium, the set of alignment marks 216 are formed on each chip of the set of chips (FIG. 2E). The alignment marks can be formed by a printing process, laser ablation process, scribing process, or other similar process.

FIG. 2A illustrates, in a side view, a temporary carrier 202 with tape 201 adhered thereto, following a first operation. In one or more implementations, the temporary carrier 202 can be either a wafer form or panel form, such as a silicon wafer or a glass substrate. In other implementations, the temporary carrier 202 is a carrier form, such as a polymeric carrier. In one or more implementations, the tape 201 is a two-sided tape, such as a thermal-release tape.

FIG. 2B illustrates, in a side view, a set of dies (chips) that are positioned on and adhered to the temporary carrier 202 using the tape 201, following a second operation. In one or more implementations, the set of dies includes at least three different types of dies. A first type of die (e.g., type A, including instances A-1 and A-2), a second type of die (e.g., type B, including instances B-1 and B-2), and a third type of die (e.g., type C, including instances C-1 and C-2) are adhered to the temporary carrier 202. In some implementations, each of the set of dies includes known good dies (KGDs) that include copper pads that are positioned so that they are ready for interconnection. In one example, each set of dies includes at least one passive chip 104 (FIG. 1), a memory chip 108 (FIG. 1), and an integrated function chip 102 (FIG. 1). In another example, each set of dies includes at least one of a through-silicon-via chip 106 (FIG. 1), a memory chip 108 (FIG. 1), and the integrated function chip 102 (FIG. 1). In one example, each die that is type A is a passive chip, each die that is type B is a memory chip, and each die that is type C is an integrated function chip 102. In another example, each die that is type A is a TSV chip 106, each die that is type B is a memory chip, and each die that is type C is an integrated function chip 102.

The set of dies, including both the first type and second type, are adhered to the temporary carrier 202 (and tape 201) “face down” such that the pads or interconnects 203 of the dies contact face toward the temporary carrier 202. In some embodiments, the set of dies are arranged in separate die units across the surface of the temporary carrier 202, such as generally illustrated in FIG. 2E. As illustrated in FIG. 2E, in one example, four sets of four different types of die (e.g., A, B, C, and D) are arranged in a pattern within a region (i.e., a unit) of the surface of the temporary carrier 202. For example, a first set of dies including the dies A-1, B-1, C-1 and D-1 are arranged and positioned within a first die unit 210 of the surface of the temporary carrier 202, a second set of dies including the dies A-2, B-2, C-2 and D-2 are arranged and positioned within a second die unit 211, a third set of dies including the dies A-3, B-3, C-3 and D-3 are arranged and positioned within a third die unit 212, and a fourth set of dies including the dies A-4, B-4, C-4 and D-4 are arranged and positioned within a fourth die unit 213. For reference, FIG. 2E includes a view of an interconnection side of each of the dies, which are disposed against the tape 201 of the temporary carrier 202 illustrated in FIG. 2B. Although FIG. 2E illustrates four dies arranged in four different die units, this is for example purposes only, the quantity of die units and the quantity of dies within each die unit are not limited. Furthermore, although FIG. 2E illustrates that each type of die is positioned in a same location in each die unit (e.g., dies A-1 through A-4 are each located in the top left corner of their respective die unit), it is understood that the same type of die can be positioned in the same or different locations within each die unit.

FIG. 2C illustrates, in a side view, the set of dies adhered to the temporary carrier 202, where a fill material 204 has been applied. In one example, each dies of the set of dies are molded in the fill material 204 to secure each die relative to each other die. In one or more implementations, the fill material 204 covers the back and sides of each die of the set of dies. In one or more implementations, the fill material 204 is an epoxy (e.g., an epoxy molding compound (EMC)) that is applied to the set of dies adhered to the temporary carrier 202, and then cured, forming a molded set of dies. In some implementations, the EMC is then resurfaced to control the total thickness variation (TTV) of the molding. The resurfacing process can include performing one or more material removal steps, such as polishing, laser ablation, etching or other useful technique.

FIG. 2D illustrates, in a side view, the molded set of dies with the tape 201 and temporary carrier 202 removed, and thus, exposing the interconnection side of each of the dies. In one or more implementations, the temporary carrier 202 and tape 201 is debonded from the molded set of dies. The top face (e.g., the top metal side of the interconnection side) of the set of dies (e.g., chiplets) are then resurfaced, using a resurfacing process 205, to allow exposure of the contact pads as well as exposure of marks (e.g., individual die fiducial marks) of each die (e.g., chiplet). In one or more implementations, each die has a pre-layout alignment mark 216 (FIG. 2E). The resurfacing process 205 can include a chemical mechanical polishing (CMP) process, a grinding process, or other similar process.

FIG. 2E illustrates, in a top view, the molded set of dies with the tape 201 and temporary carrier 202 removed (e.g., debonded). As noted above, the molded set of dies are illustrated as four die units (210-213), each die unit includes one instance of a die from a first type of die (e.g., A-1 of A for the first die unit 210), one instance of a die from a second type of die (e.g., B-1 of B for the first die unit 210), one instance of a die from a third type of die (e.g., C-1 of C for the first die unit 210), and one instance of a die from a fourth type of die (e.g., D-1 of D for the first die unit 210). Each die has at least one alignment mark 216 that is used to define its position and orientation relative to other die within a die unit and/or with other die within other die units. Due to placement accuracy issues and movement of the die in prior performed processes, such as the processes performed during FIGS. 2B-2D, the relative position and orientation of each die within each die unit can vary die unit-to-die unit, at the state of the process sequence shown in FIG. 2E. In one or more embodiments, the alignment mark 216 is a “+” or “x” shape. Any suitable shape, type, or form of alignment mark, or combination of alignment marks, can be applied to the molded dies in other embodiments. In one or more embodiments, a die identifier is also applied, for example a barcode, or a QR code or other type of two dimensional barcode.

At operation 306, each of the alignment marks 216 of the molded set of dies are mapped by use of an optical inspection system that includes a camera and a system controller that includes a processor (CPU), nonvolatile memory and I/O components. For example, position and orientation information of the molded set of dies is determined based on the mapping of the alignment marks 216. The molded set of dies (i.e. chips) having the alignment marks 216 are scanned, analyzed and stored in memory of a system controller. Each chip (die) shift and orientation is scanned and recorded, for example in a graphic data system (GDS) file. In one or more embodiments, all digital map input and fiducial correction information is computed and consolidated at device level test as a file (e.g., GDS file) for separated interposer patterning use. As such, in some embodiments, the alignments marks 216 are die level alignment marks for use with a digital lithography technology (DLT) patterning process.

Some more of the advantages of this approach include that there is no reticle size limit on the interconnection pattern. Also, the digitalized interconnect redistribution substrate unit manufacturing process can be also decoupled from a single substrate manufacturing batch sequence and thus substrate units can be produced with other types of multiple-chiplet unit substrates as needed, which will provide additional manufacturing flexibility. In some embodiments, the recorded GDS file can also be reused in cases where the process needs to be repeated, or the data can be further pattern optimized through the substrate via interconnect and chiplet top metal patterning mapping. Moreover, it is easy to scale up the described operations to cover full multiple chiplet connection module, or both.

At operation 308, an interconnect substrate 218 (which may also be referred to as a direct interconnect land substrate (DILS)) is formed based on the scanned set of dies (i.e., the mapping). The interconnect substrate 218 is bonded to the multichip module 200 (i.e., the molded set of chips). The operations for forming the interconnect substrate 218 are illustrated in FIGS. 2F-2M.

FIG. 2F illustrates, in a side view, the interconnect substrate 218. In one or more embodiments, the interconnect substrate 218 includes a first interconnect layer 220 and a direct interconnect portion that includes the base substrate 222. In one example, the interconnect substrate 218 includes the first interconnect layer 220 which includes an epoxy material, an ABF material, a polyimide material, or other useful dielectric material, and the base substrate 222 comprises silicon (Si), silicon oxide or silicon dioxide (SiOx), glass, aluminum nitride (AlN), or silicon carbide (SiC). In one or more embodiments, the first interconnect layer 220 is a first redistribution layer (RDL) structure. The base substrate 222 may comprise silicon (Si), silicon oxide or silicon dioxide (SiOx), glass, aluminum nitride (AlN), silicon carbide (SiC), an organic material, or another type of suitable material. The base substrate 222 can be also include a built-in MIM capacitor, deep trench capacitor, inductor, resistor, or other active circuits. In some embodiments, the base substrate 222 is silicon, and the CTE is improved over conventional techniques that use other substrate materials. In one or more embodiments, the interconnect substrate 218 provides improved mechanical strength to support a fine pitched redistribution layer (RDL) (e.g., less than about 2/2 um, which is considered a typical multichip module (MCM) fanout limitation). In one or more embodiments, the interconnect substrate 218 provides relatively increased strength between dies without deformation, better thermal cycle reliability, or both. In some embodiments the interconnect substrate 218 includes one or more active circuit or passive components. In other embodiments the interconnect substrate 218 excludes includes active circuit and passive components. In one or more embodiments, the interconnect substrate 218 includes a DLT printing alignment mark and/or a laser scribed (but not limited to laser) barcode and alignment mark, for example for quality tracking and for a next level RDL stacking scheme or an extra added-on substrate packaging scheme.

In one or more examples, the base substrate 222 and the first interconnect layer 220 are etched in a pattern that is defined by the mapping process, as discussed in relation to operation 306. FIG. 2G illustrates, in a side view, the interconnect substrate 118 following an etching process to form a first plurality of patterned vias 224. In one example, the interconnect substrate 218 is etched (i.e. patterned) to provide the first plurality of patterned vias 224 therethrough, and in some cases alignment marks. The first plurality of patterned vias 224 may be etched through both the first interconnect layer 220 and the base substrate 222. The etching process can include the use of a digital lithography technology (DLT) tool that includes the use of one or more lasers and steering optics to form features in the interconnect substrate 218. DLT may also be referred to as “direct laser imaging” in some examples. DLT is a type of patterning process used in semiconductor and/or flat panel manufacturing to pattern and etch extremely small features in a substrate by use of a laser source. In DLT, the mask used to transfer the pattern onto the substrate is created digitally, using computer-aided design (CAD) software created from the graphic data system (GDS) file described above. As such, DLT may also be referred to as “maskless,” whether DLT uses a pattern or digital “mask.”

In one or more embodiments, the interconnect substrate 218 is etched according to a pattern to form the first plurality of patterned vias 224 that are positioned and aligned based on their relative position and orientation variation within each of the die units, as determined by the data (position and orientation information) collected from the scanning process (i.e., the mapping during operation 306) discussed above in relation to FIG. 2E. In one or more embodiments, the pattern can be inspected (e.g., using an automated optical inspection (AOI) system) to ensure alignment of the interconnect substrate 218 with the set of dies (e.g., check for 100% alignment with multiple dies).

FIG. 2H illustrates a top view of the first plurality of patterned vias 224 formed through the interconnect substrate 218 within an interconnect substrate unit that corresponds to each of the die units (e.g., die units 210-213 shown) that include the multiple die (e.g., four die) within each die unit that can have different placement orientations relative to each other within each die unit. For example, a first interconnect substrate unit 240 corresponds to the first die unit 210, a second interconnect substrate unit 241 corresponds to the second die unit 211, a third interconnect substrate unit 242 corresponds to the third die unit 212, a fourth interconnect substrate unit 243 corresponds to the fourth die unit 213. The position of the first plurality of patterned vias 224 created for each die within each interconnect substrate unit of the interconnect substrate 218 can vary unit-to-unit based on the variation in the position and orientation of each of the die within each unit within the molded set of dies. For example, each of the first plurality of patterned vias 224 are positioned within an opening 229 that is configured to connect with an interconnects 203 of a plurality of interconnects formed on each chip (i.e. die) in the multichip module 200 based on the mapping of the alignment marks 216. Stated differently, the first plurality of patterned vias 225 are positioned within an openings 229 that are aligned and positioned to form a connection with the interconnects 203 of each chip (i.e. die) in the multichip module 200 based on the position and orientation information of each chip in the multichip module 200.

In some embodiments, the first interconnect layer 220 and the direct interconnection portions (direct connection layers), such as the base substrate 222, are etched prior to attachment to the molded set of dies. In other embodiments, one or more interconnect layers can be formed on the first interconnect layer 220 of the interconnect substrate 218 that is attached to the molded set of dies at a later step in the processing sequence (e.g., see FIG. 2M).

In one or more embodiments, a base substrate thinning process is performed. In some embodiments, the base substrate thinning process is performed before the first plurality of patterned vias 224 are etched. In other embodiments, the base substrate thinning process is performed after the first plurality of patterned vias 224 are etched. In one or more embodiments, the base substrate thickness can be modulated.

In one or more examples, the interconnect substrate 218 is then diced into individual interconnect units, as shown by the formation of a separating feature 247. FIG. 2I illustrates, in a side view, a step where the interconnect substrate 218 has been diced into individual interconnect units so that each individual interconnect unit can be separately attached to each die unit of the molded set of dies. In one of more embodiments, the interconnect substrate 218 (e.g., a DILS) is diced into individual interconnect units by use of a DLT type process that forms the separating features 247. In some embodiments, dicing the interconnect substrate 218 into individual interconnect units and then bonding the individual interconnect units to portions of the molded set of dies will reduce the warpage and stress created in the individual die package units and individual die connections due to mechanical and thermal fluctuations created during subsequent processing steps. For example, the interconnect substrate 218 is diced into the first interconnect substrate unit 240, the second interconnect substrate unit 241, and so on. In one example, the first interconnect substrate unit 240 is configured to be affixed over first die unit 210, the second interconnect substrate unit 241 is configured to be affixed over the second die unit 211, and so on.

The interconnect substrate 218 may be aligned so that each individual interconnect unit is attached to the corresponding die unit. Stated differently the interconnect substrate 218 is aligned so that the interconnects 203 on each die (i.e. chip) in the molded set of dies (i.e., the set of chips) are aligned the first plurality of patterned vias 225. FIG. 2J illustrates, in a side view, the interconnect substrate 218 being aligned so that it can be attached to the molded set of dies. For example as further described above, each unit of interconnect substrate 218 (e.g., DILS unit) has an associated specific correction data (e.g., digital GDS data) that is used to position and align the pattern formed in the corresponding individual interconnect substrate units to a portion of the mating molded set of die. In some embodiments, because the correction data (e.g., GDS data) is digitalized, the correction data can be re-printed or re-optimized to form an improved interconnection structure. As noted above, the first interconnect substrate unit 240 is aligned over first die unit 210 and the second interconnect substrate unit 241 is aligned over the second die unit 211. Stated differently, the first interconnect substrate unit 240 is aligned with dies A-1, B-1, and C-1, and the second interconnect substrate unit 241 is aligned with dies A-2, B-2, and C-2.

The interconnect substrate 218 is then attached (bonded) to the molded set of dies (i.e., the multichip module 200) based on the alignment of the interconnect substrate units. FIG. 2K illustrates, in a side view, the interconnect substrate 218 being attached to the molded set of dies. As noted above, the first interconnect substrate unit 240 of the interconnect substrate 218 is attached to the first die unit 210 and the second interconnect substrate unit 241 of the interconnect substrate 218 is attached to the second die unit 211. In some embodiments, the pattern of first plurality of patterned vias are inspected by AOI to ensure alignment (e.g., 100% alignment) with the multiple dies of the set of dies. In some embodiments, the interconnect substrate 218 is diced as individual interconnect substrate units, which breaks the process inducing warpage and stress interference. The units of the diced individual interconnect substrate units are placed (e.g., via pick and place), and attached (e.g., using a die attach film (DAF) film or diffusion bond) on the assigned units (e.g., chiplets module) as an individual solid unit, for example, to decouple the global stress and warpage interference. According to one or more embodiments, following attachment, the openings 229 can be further processed to expose the metal contact surface positioned at the bottom of the first plurality of patterned vias 224. In some embodiments, a desmear process for the DAF film, or a plasma asher (plasma ashing) process can be used.

Next, the first plurality of patterned vias 224 are filled to form a first plurality of metal interconnects 225a. FIG. 2L illustrates, in a side view, the interconnect substrate 218 that has the first plurality of metal interconnects 225a formed therein. The first plurality of metal interconnects 225a, which are aligned with and configured to connect to the electrical connections of the die, can be formed by physical vapor deposition (PVD) process, an electroless plating process and/or an electroplating process. The first plurality of metal interconnects 225a fill the holes formed by the first plurality of patterned vias 224. In one or more embodiments, a copper barrier seed (CuBS) group of layers can be formed according to any suitable technique, and the first plurality of patterned vias 224 may be filled according to any suitable deposition technique (e.g., bulk fill on the barrier seed layer). Additionally, metalized traces 226 are formed in the first interconnect layer 220 of the interconnect substrate 218. In some embodiments, active devices (e.g., transistors), passive devices (e.g., resistors, capacitors), or both are formed on in the first interconnect layer 220.

In some embodiments, the connection between the interconnect substrate 218 (interposer) vias and the contacts of the chiplets (e.g., the pads of the chiplet, die or chip), which are not a solder interface, have a superior Cu line to Cu via interface connection (e.g., lowered resistivity) than prior conventional solder techniques. In some embodiments, the via density (input/output (I/O) area density is equal to or denser than prior techniques (e.g., a traditional 2.5D through substrate via (TSV) interposer approach). In some embodiments, the RDL line density is at least equal to Si interposer or Si bridge level, for example due to a similar rigid interconnect substrate (e.g., DILS substrate) flatness.

At operation 310, additional interconnect layers having interconnects that are tailored to both the first plurality of metal interconnects 225a and to be attached stacked chips may be formed over the first interconnect layer 220. In another example, the additional interconnect layers may be formed before the interconnect substrate 218 is attached to the molded set of dies. FIG. 2M illustrates, in a side view, a second interconnect layer 230 (e.g., second RDL type layer) added to the interconnect substrate 218 that has been attached to the molded set of dies. Although only a second interconnect layer 230 is added to the interconnect substrate 218, this is for example purposes only and multiple additional interconnect layers may be added to the interconnect substrate 218.

In one or more embodiments, the second interconnect layer 230 are a second RDL layer structure. In other embodiments the second interconnect layer 230 is a C4/Cu pillar layer. The second interconnect layer 230 be added after via formation of the interconnect substrate, for example for next level substrate integration. In one or more embodiments, prior to attaching the second interconnect layer 230, an inter-die fill can be applied to (formed on) the interconnect substrate (e.g., as illustrated in FIG. 2L). In some embodiments, the inter-die fill is spun on.

In one or more embodiments, the second interconnect layer 230 include a second interconnect substrate (e.g., which may be or be referred to as a second direct interconnect land interposer (DILI) herein, and the first interconnect layer also be or be referred to as a first DILI). The vias of the interconnect layer (e.g., interposer, DILI) can be form a connection to the chiplets without a solder interface, which can provide a superior copper line to copper via interface (e.g., more reliable, lower resistivity). In some embodiments, after the second interconnect layer 230 are attached, metalized traces of an interconnect layer on top of the second interconnect layer 230 can be processed (e.g., by a DLT tool) according to a file including die shift and orientation information (e.g., a second GDS file, or a second set of data in the GDS file associated with the previously formed interconnect layer or layers onto which the second interconnect layer 230 are to be attached. In some embodiments, the density can be equal to a silicon Si interposer or silicon bridge level approach due to a similar rigid DILS substrate flatness. According to one or more embodiments, the interconnect substrate and layers can be extended to further layers using further DILI (e.g., including a direct interconnect substrate and RDL), each of which can include active or passive components, RDL, and so on.

While the foregoing is directed to embodiments of the present disclosure, other and further embodiments of the disclosure may be devised without departing from the basic scope thereof. The present disclosure also contemplates that one or more aspects of the embodiments described herein may be substituted in for one or more of the other aspects described. The scope of the disclosure is determined by the claims that follow.

What is claimed is:

1. A method of forming a multichip module, comprising:
molding a set of chips in a medium to secure each chip relative to each other chip;
mapping a position and orientation of the chips within the molded set of chips based on alignment marks disposed on each chip within the molded set of chips;
forming an interconnect substrate comprising:
forming a first interconnect layer over a base substrate;
patterning the first interconnect layer to include a first plurality of patterned vias that are patterned based at least in part on the mapping; and
bonding the interconnect substrate the multichip module, wherein bonding comprises positioning and aligning the interconnect substrate to the molded set of chips such that interconnects of each chip within the molded set of chips are aligned with the first plurality of patterned vias formed in the interconnect substrate.

2. The method of claim 1, further comprising forming metal interconnects in first plurality of patterned vias.

3. The method of claim 1, further comprising forming a second interconnect layer over the first interconnect layer.

4. The method of claim 1, further comprising adhering the set of chips to a temporary carrier prior to molding the set of chips in the medium.

5. The method of claim 1, wherein the set of chips are adhered to a temporary carrier via tape.

6. The method of claim 1, wherein mapping a position and orientation of the chips within the molded set of chips comprises scanning and analyzing each alignment mark of each chip to determine an orientation and chip shift of each chip and storing the orientation and chip shift of each chip.

7. The method of claim 3, wherein the first interconnect layer is a first redistribution layer (RDL) and the second interconnect layer is a second (RDL).

8. The method of claim 1, wherein the first plurality of patterned vias are formed through the first interconnect layer and the base substrate.

9. A method of forming a multichip module, comprising:
forming a set of alignment marks on a set of dies to be integrated into a multichip module, the set of dies comprising a first die unit comprising first dies and a second die unit comprising second dies, each die having at least one alignment mark;
molding the set of dies in a medium to secure each die relative to each other die;
mapping each alignment mark of each die in the set of dies that are molded in the medium;
forming an interconnect substrate comprising:
forming a first interconnect layer over a base substrate;
patterning the first interconnect layer to include a first plurality of patterned vias that are patterned based at least in part on the mapping; and
dicing the interconnect substrate into individual interconnect substrate units including a first interconnect substrate unit corresponding to the first die unit and a second interconnect substrate unit corresponding to the second die unit; and
bonding the first interconnect substrate unit to the first die unit and the second interconnect substrate unit to the second die unit.

10. The method of claim 9, further comprising forming metal interconnects in first plurality of patterned vias.

11. The method of claim 9, further comprising forming a second interconnect layer over the first interconnect layer.

12. The method of claim 11, wherein the first interconnect layer is a first redistribution layer (RDL) and the second interconnect layer is a second RDL.

13. The method of claim 9, further comprising adhering the set of chips to a temporary carrier prior to molding the set of chips in the medium.

14. The method of claim 9, wherein the set of chips are adhered to a temporary carrier via tape.

15. The method of claim 9, wherein mapping each alignment mark of each die in the set of dies comprising scanning and analyzing each alignment mark of each die to determine an orientation and die shift of each die and storing the orientation and die shift of each die.

16. The method of claim 9, wherein the first plurality of patterned vias are formed through the first interconnect layer and the base substrate.

17. A packaged multichip module, comprising:
a set of chips molded in a medium, each chip having at least one alignment mark; and
an interconnect substrate bonded to the set of chips, the interconnect substrate comprising a first interconnect layer formed over a base substrate, and a first plurality of patterned vias formed through the base substrate and the first interconnect layer that are patterned based on a position and orientation of the chips determined based at least in part on a mapping of each alignment mark.

18. The packaged multichip module of claim 17, further comprising forming a second interconnect layer formed over the first interconnect layer.

19. The packaged multichip module of claim 18, wherein the first interconnect layer is a first redistribution layer (RDL) and the second interconnect layer is a second RDL.

20. The packaged multichip module of claim 17, wherein the medium comprises tape.
